(19) United States
(12) Patent Application Publication
(10) Pub. No.: US 2009/0121280 A1
(43) Pub. Date: May 14, 2009

(54) SEMICONDUCTOR DEVICES, METHODS OF FORMING THE SEMICONDUCTOR DEVICES AND METHODS OF OPERATING THE SEMICONDUCTOR DEVICES

(75) Inventor: Kwang-Wook Koh, Seoul (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/269,771

(22) Filed: Nov. 12, 2008

(30) Foreign Application Priority Data
Nov. 14, 2007 (KR) 10-2007-0116146

(51) Int. Cl. H01L 29/792

(52) U.S. Cl. 257/324; 257/E29.309

(57) ABSTRACT

Described are a semiconductor device, methods of forming the semiconductor device and methods of operating the semiconductor device. The semiconductor device includes a gate electrode and laminated charge trap layers interposed between substrates. The methods of forming the semiconductor device include forming a gate stacked structure including insulating layers having a different etching selectivity, forming spaces on sidewalls of the gate stacked structure using an etching selectivity and forming charge trap layers in the spaces. The methods of operating the semiconductor device include programming trap layers by controlling a voltage applied to a gate electrode.

### CROSS-REFERENCE TO RELATED APPLICATIONS

This U.S. non-provisional patent application claims priority under 35 U.S.C. §119 to Korean Patent Application No. 10-2007-0116146, filed on Nov. 14, 2007, the entire contents of which are hereby incorporated by reference.

### BACKGROUND

Exemplary embodiments disclosed herein relate to semiconductor devices having an increased capacity, methods of forming the semiconductor devices and methods of operating the semiconductor devices.

### SUMMARY

Exemplary embodiments provide a semiconductor device. The semiconductor device may include a gate electrode on a substrate; a first charge trap layer interposed between the substrate and the gate electrode; a second charge trap layer which is interposed between the substrate and the gate electrode and is spaced apart from the first charge trap layer; a third charge trap layer interposed between the first charge trap layer and the gate electrode; a fourth charge trap layer which is interposed between the second charge trap layer and the gate electrode and is spaced apart from the third charge trap layer; and an impurity region in the substrate.

Exemplary embodiments provide methods of forming a semiconductor device. The methods of forming a semiconductor device may include providing a stacked structure including a first barrier layer, a middle insulating layer, a second barrier layer and a conductive layer that are sequentially stacked on a substrate; forming spaces by removing a portion of the first and second barrier layers exposed on both sidewalls of the stacked structure from the sidewalls; forming charge trap layers in the spaces; and forming an impurity region in the substrate adjacent to the stacked structure.

Exemplary embodiments provide methods of operating a semiconductor device. The methods of operating a semiconductor device including a gate electrode on a substrate, a first charge trap layer interposed between the substrate and the gate electrode, a second charge trap layer which is interposed between the substrate and the gate electrode and spaced apart from the first charge trap layer, a third charge trap layer interposed between the first charge trap layer and the gate electrode, a fourth charge trap layer interposed between the second charge trap layer and the gate electrode, a first impurity region in the substrate adjacent to the first charge trap layer and a second impurity region in the substrate adjacent to the second charge trap layer, the methods may include applying a higher voltage to the first impurity region than the second impurity region and injecting electrons into the first trap layer or third trap layer by applying a program voltage to the gate electrode.

### BRIEF DESCRIPTION OF THE DRAWINGS

The accompanying figures are included to provide a further understanding of the inventive concepts described herein, and are incorporated in and constitute a part of this specification. The drawings illustrate exemplary embodiments of inventive concepts described herein and, together with the description, serve to explain principles of the inventive concepts described herein. In the figures:

FIG. 1 is a cross-sectional view of a semiconductor device in accordance with an embodiment.

FIGS. 2A and 2B are cross-sectional views of a semiconductor device in accordance with modified embodiments.

FIG. 3 is a cross-sectional view of a semiconductor device in accordance with another embodiment.

FIGS. 4A and 4B are cross-sectional views of a semiconductor device in accordance with other modified embodiments.

FIGS. 5A and 5B are circuit views illustrating a method of operating a semiconductor device in accordance with some embodiments.

FIGS. 6 through 11 are cross-sectional views illustrating a method of forming a semiconductor device in accordance with some embodiments.

FIGS. 12 through 17 are cross-sectional views illustrating a method of forming a semiconductor device in accordance with some other embodiments.

FIG. 18 is a schematic view of a modular semiconductor device including a semiconductor device in accordance with some embodiments.

### DETAILED DESCRIPTION OF THE EMBODIMENTS

Embodiments of inventive concepts will be described more fully hereinafter with reference to the accompanying drawings. These embodiments may, however, be realized in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first region/layer could be termed a second region/layer, and, similarly, a second region/layer could be termed a first region/layer without departing from the teachings of the disclosure.

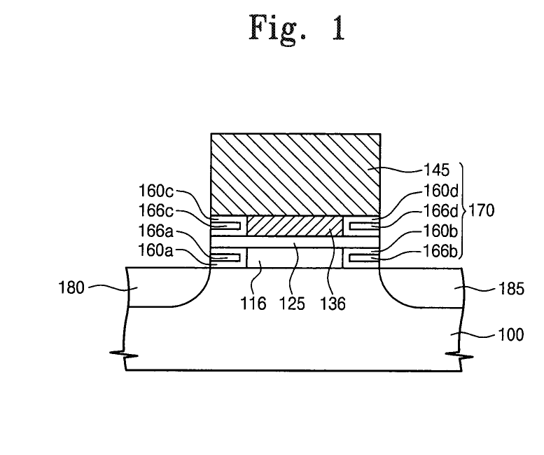

Referring to FIG. 1, a semiconductor device according to an embodiment will be described.

Referring to FIG. 1, a substrate 100 is provided. The substrate 100 may be a semiconductor substrate such as silicon wafer. The substrate 100 may also be silicon on insulator (SOI). A gate structure 170 including a plurality of charge trap layers 166a, 166b, 166c and 166d may be disposed on the substrate 100. The charge trap layers 166a, 166b, 166c and 166d may include a charge trap site (e.g., silicon nitride and/or nano crystal). The gate structure 170 may include two sides which are in parallel to each other. Impurity regions 180 and 185 are defined in the substrate 100, and are each respectively adjacent to the sides.

The gate structure 170 may include a conductive pattern 145 and the conductive pattern 145 may constitute a gate electrode. The conductive pattern 145 may include a conductive polysilicon. A first charge trap layer 166a and a second charge trap layer 166b may be interposed between the conductive pattern 145 and the substrate 100. The first and second charge trap layers 166a and 166b may be separated from each other by a first barrier 116. The first barrier 116 may include an insulating material (e.g., a silicon oxide layer). A third charge trap layer 166c may be interposed between first charge trap layer 166a and the conductive pattern 145. A fourth charge trap layer 166d may be interposed between the second charge trap layer 166b and the conductive pattern 145. The third and fourth charge trap layers 166c and 166d may be separated from each other by a second barrier 136. The second barrier 136 may include a conductive material (e.g., a conductive polysilicon germanium) having an etching selectivity different from a conductive material of the conductive pattern 145. Side surfaces of the first and third charge trap layers 166a and 166c may be aligned with one side surface of the gate structure 170. Side surfaces of the second and fourth charge trap layers 166b and 166d may be aligned with the opposite side surface of the one side surface of the gate structure 170.

The first and second charge trap layers 166a and 166b may have the same charge storage capacitance. The first and second charge trap layers 166a and 166b may be symmetrical with respect to a central axis of the gate structure 170. The third and fourth charge trap layers 166c and 166d may have the same charge storage capacitance. The third and fourth charge trap layers 166c and 166d may be symmetrical with respect to a central axis of the gate structure 170.

The charge trap layers 166a, 166b, 166c and 166d are respectively surrounded by a first insulating pattern 160a, a second insulating pattern 160b, a third insulating pattern 160c and a fourth insulating pattern 160d except side surfaces of the charge trap layers 166a, 166b, 166c and 166d exposed to both sides of the gate structure 170. The insulating patterns 160a, 160b, 160c and 160d may include a silicon oxide. A middle insulating pattern 125 may be interposed between the first and second barriers 116 and 136. The middle insulating pattern 125 may include, different from the first barrier 116, a high dielectric constant material such as an aluminum oxide layer, a hafnium aluminum oxide layer, a lanthanum aluminum oxide layer and/or a lanthanum oxide layer. The middle insulating pattern 125 may be interposed between the first and second charge trap layers 166a and 166b and between the third and fourth charge trap layers 166c and 166d.

For example, the first insulating pattern 160a may be a tunnel insulating layer of the first charge trap layer 166a and the second insulating pattern 160b may be a tunnel insulating layer of the second charge trap layer 166b. The insulating pattern on the first charge trap layer 166a and the second charge trap layer 166b may be a blocking layer. The first insulating pattern 160a, the first trap layer 166a, the third insulating pattern 160c and the middle insulating pattern 125 may be a tunnel insulating layer of the third charge trap layer 166c. The second insulating pattern 160b, the second charge trap layer 166b, the fourth insulating pattern 160d and the middle insulating pattern 125 may be a tunnel insulating layer of the fourth charge trap layer 166d. The insulating pattern on the third charge trap layer 166c and fourth charge trap layer 166d may be a blocking layer.

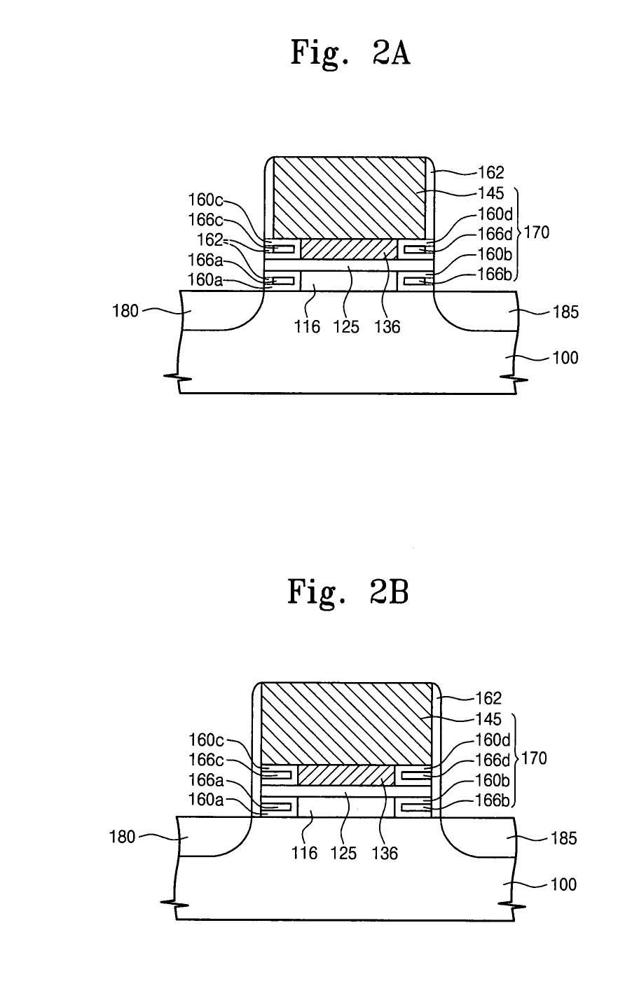

Referring to FIGS. 2A and 2B, semiconductor devices according to modified embodiments are described. A description of common features already discussed above will be omitted for brevity.

Spacers 162 may be further provided on side surfaces of the conductive pattern 145 and the charge trap layers 166a, 166b, 166c and 166d exposed on the side surfaces of the gate structure 170 of FIG. 1. For instance, the spacer 162 may include silicon oxide and/or silicon oxynitride. The charge trap layers 166a, 166b, 166c and 166d may be protected by the spacers 162.

The spacer 162 may be a layer including the same material entirely that is continuously formed on a side surface of the gate structure 170 (FIG. 2B). Or, the spacer 162 may be a discontinuous layer that is selectively formed on only exposed side surfaces of the conductive pattern 145 and the charge trap layers 166a, 166b, 166c and 166d (FIG. 2A).

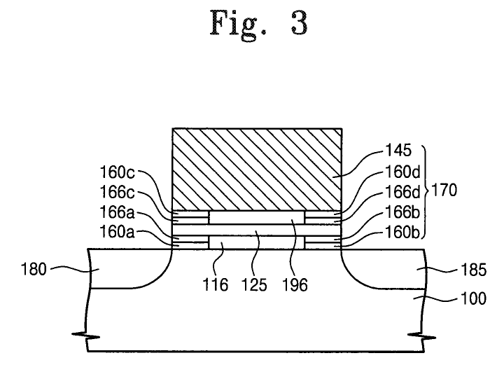

Referring to FIG. 3, a semiconductor device according to another embodiment will be described. A description of common features already discussed in FIG. 1 will be omitted or only briefly described.

A gate structure 170 including a plurality of charge trap layers 166a, 166b, 166c and 166d may be disposed on a substrate 100. The charge trap layers 166a, 166b, 166c and 166d may include a charge trap site (e.g., silicon nitride and/or nano crystal). The gate structure 170 may include two sides which are in parallel to each other. Impurity regions 180 and 185 are defined in the substrate 100, and are each respectively adjacent to the sides.

The gate structure 170 may include a conductive pattern 145 and the conductive pattern 145 may constitute a gate electrode. The conductive pattern 145 may include a conductive polysilicon. A first charge trap layer 166a and a second charge trap layer 166b may be interposed between the conductive pattern 145 and the substrate 100. The first and second charge trap layers 166a and 166b may be separated from each other by a first barrier 116. The first barrier 116 may include an insulating material (e.g., a silicon oxide layer). A third charge trap layer 166c may be interposed between first charge trap layer 166a and the conductive pattern 145. A fourth charge trap layer 166d may be interposed between the second charge trap layer 166b and the conductive pattern 145. The third and fourth charge trap layers 166c and 166d may be separated from each other by a second barrier 196. The second barrier 196 may include the same material as the first barrier 116.

The first charge trap layer 166a and the second charge trap layer 166b may have the same charge storage capacitance. The third charge trap layer 166c and the fourth charge trap layer 166d may have the same charge storage capacitance.

A first insulating pattern 160a may be interposed between the first charge trap layer 166a and the substrate 100. A second insulating pattern 160b may be interposed between the second charge trap layer 166b and the substrate 100. A third insulating pattern 160c may be interposed between the third charge trap layer 166c and the conductive pattern 145. A fourth insulating pattern 160d may be interposed between the fourth charge trap layer 166d and the conductive pattern 145. The insulating patterns 160a, 160b, 160c and 160d may include silicon oxide. A middle insulating pattern 125 may be interposed between the first and second barriers 116 and 196. The middle insulating pattern 125 may include a material different from the first and second barriers 116 and 196. The middle insulating pattern 125 may be a high dielectric constant material such as an aluminum oxide layer, a hafnium aluminum oxide layer, a lanthanum aluminum oxide layer and/or a lanthanum oxide layer. The middle insulating pattern 125 may be interposed between the first and second charge trap layers 166a and 166b and between the third and fourth charge trap layers 166c and 166d.

For example, the first insulating pattern 160a may be a tunnel insulating layer of the first charge trap layer 166a and the second insulating pattern 160b may be a tunnel insulating layer of the second charge trap layer 166b. In this instance, the middle insulating pattern 125 may be a blocking layer. The first insulating pattern 160a, the first charge trap layer 166a and the middle insulating pattern 125 may be a tunnel insulating layer of the third charge trap layer 166c. The second insulating pattern 160b, the second charge trap layer 166b and the middle insulating pattern 125 may be a tunnel of the fourth charge trap layer 166d. The third and fourth insulating patterns 160c and 160d on the third and fourth charge trap layers 166c and 166d may be blocking layers.

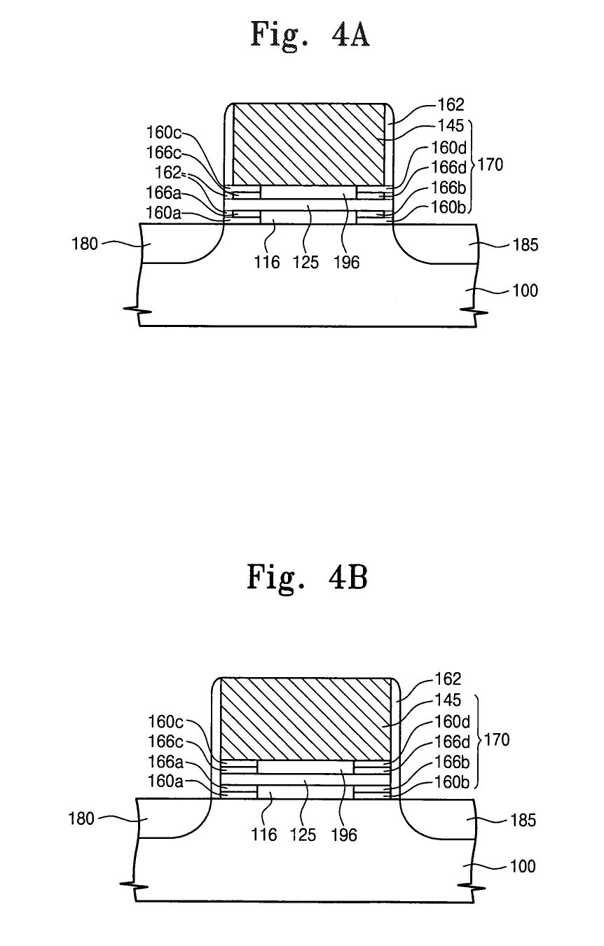

Referring to FIGS. 4A and 4B, a semiconductor device according to other modified embodiments. A description of common features already discussed in FIG. 1 will be omitted for brevity.

Spacers 162 may be further provided on side surfaces of the conductive pattern 145 and the charge trap layers 166a, 166b, 166c and 166d exposed on sides of the gate structure of FIG. 3. For instance, the spacer 162 may include silicon oxide and/or silicon oxynitride. The charge trap layers 166a, 166b, 166c and 166d may be protected by the spacers 162.

The spacer 162 may be a layer including the same material entirely that is continuously formed on a side surface of the gate structure 170 (FIG. 4B). The spacer 162 may be a discontinuous layer that is selectively formed on only exposed side surfaces of the conductive pattern 145 and the charge trap layers 166a, 166b, 166c and 166d (FIG. 4A).

Referring to FIGS. 1b through 5B and a table 1, a method of operating a semiconductor device according to an embodiment will be described.

TABLE 1

| | R1 | R2 | V_{gate} |
|---|---|---|---|
| PGM1 | 5 | GND | 4.5 |
| PGM3 | 5 | GND | 7.5 |
| PGM2 | GND | 5 | 4.5 |
| PGM4 | GND | 5 | 7.5 |
| ERS1 | 5 | F | −4.5 |
| RES3 | 5 | F | −7.5 |
| ERS2 | F | 5 | −4.5 |
| ERS4 | F | 5 | −7.5 |
| Block ERS | 7.5 | 7.5 | 0 |
| READ 1, 3 | GND | 1.0 | 3.3 |
| READ 2, 4 | 1.0 | GND | 3.3 |

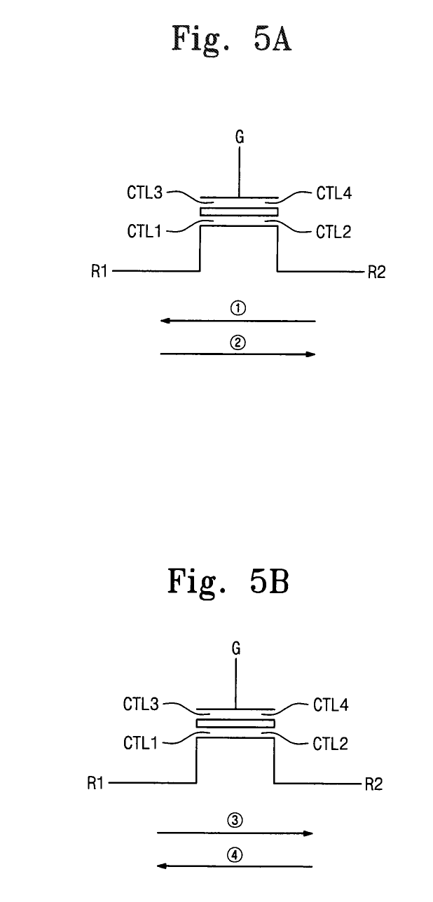

Referring to FIG. 5A, a program method of a semiconductor device according to an embodiment is described. For example, a program operation (PGM1) applied to a first charge trap layer (CTL1) may be performed. A gate voltage (V_{gate}) applied to a selected conductive pattern (hereinafter, it is referred to as ‘gate electrode’) (G) is a first program voltage (V_{pgm}1) and the first program voltage (V_{pgm}1) of 4.5V may be applied. Simultaneously, a power supply voltage (e.g., 5.0V) may be applied to a first impurity region (R1) adjacent to the first charge trap (CTL1) and a ground voltage may be applied to a second impurity region (R2). Thus, charges are moved, so that a program may be performed toward a first direction \textcircled{1}. Charges may be injected into the first charge trap layer (CTL1) through the first insulating pattern 160a by voltages applied to the first impurity region R1, the second impurity region R2 and the gate electrode (G).

When a third program operation (PGM3) applied to the third charge trap layer (CTL3) is performed, a third program voltage (V_{pgm}3) (e.g., 7.5V), which is higher than the first program voltage (V_{pgm}1) may be applied to the gate electrode (G). Simultaneously, a power supply voltage Vcc (e.g., 5.0V) may be applied to a first impurity region (R1) of the first charge trap (CTL1) side and a ground voltage may be applied to a second impurity region (R2). Thus, charges are moved, so that a program may be performed toward a first direction \textcircled{1}. Charges may be injected into the third charge trap layer (CTL3) through the first insulating pattern 160a, the first charge trap layer 166a, the middle insulating pattern 125 and/or the third insulating pattern 160c by voltages applied to the impurity regions R1 and R2, and the gate electrode (G). Using such a procedure, the charges may also be simultaneously injected into the first charge trap layer (CTL1). These charges may be injected into only the third charge trap layer (CTL3) by increasing the voltage. The charges may include charges formed in a channel region and/or charges trapped in the first charge trap layer (CTL1).

When a second program operation (PGM2) applied to the second charge trap layer (CTL2) is performed, a second program voltage (V_{pgm}2) (e.g., 4.5V) may be applied to the gate electrode (G). Simultaneously, a power supply voltage Vcc (e.g., 5.0V) may be applied to a second impurity region (R2) adjacent to the second charge trap (CTL2) and a ground voltage may be applied to a second impurity region (R1). Thus, charges are moved, so that a program may be performed toward a first direction \textcircled{2}. Charges may be injected into the second charge trap layer (CTL2) through the second insulating pattern 160b by voltages applied to the impurity regions R1 and R2, and the gate electrode (G).

When a fourth program operation (PGM4) applied to the fourth charge trap layer (CTL4) is performed, a fourth program voltage (V_{pgm}4) (e.g., 7.5V) may be applied to the gate electrode (G). At this time, a power supply voltage Vcc (e.g., 5.0V) may be applied to a second impurity region (R2) and a ground voltage may be applied to a first impurity region (R1). Thus, charges are moved, so that a program may be performed toward a second direction \textcircled{2}. Charges may be injected into the fourth charge trap layer (CTL4) through the second insulating pattern 160b, the second charge trap layer 166b, the middle insulating pattern 125 and/or the fourth insulating pattern 160d by voltages applied to the impurity regions R1 and R2, and the gate electrode (G). Using such a procedure, the charges may also be simultaneously injected into the second charge trap layer (CTL2). These charges may be injected into only the fourth charge trap layer (CTL4) by increasing the voltage. The charges may include charges formed in a channel region and/or charges trapped in the second charge trap layer (CTL2).

A method of erase operation of a semiconductor device according to an embodiment will be described. An erase voltage (Vₑᵣₐₛₑ) (e.g., greater than 7.5V) may be applied to a bulk (e.g., a well region) of the substrate including the gate structure 170 formed thereon during block erase operation (ERS). A voltage of 0 V or −4.5V may be applied to the selected gate electrode (G). Simultaneously, the impurity regions (R1 and R2) may be floated, or a voltage of about 7.5V may be applied to the impurity regions (R1 and R2). Thus, data may be block-erased.

When data stored in the first charge trap layer (CTL1) is selectively erased (ERS1), a first erase voltage (e.g., −4.5V) may be applied to the gate electrode (G). Simultaneously, a power supply voltage (Vcc) (e.g., 5.0V) is applied to the first impurity region (R1) and the second impurity region (R2) may be floated.

When data stored in the third charge trap layer (CTL3) is selectively erased (ERS3), a third erase voltage (e.g., −7.5V) may be applied to the gate electrode (G). Simultaneously, a power supply voltage (Vcc) (e.g., 5.0V or more) is applied to the first impurity region (R1) and the second impurity region (R2) may be floated. Data trapped in the first charge trap layer (CTL1) may be also simultaneously erased.

When data stored in the second charge trap layer (CTL2) is selectively erased (ERS2), a second erase voltage (e.g., −4.5V) may be applied to the gate electrode (G). Simultaneously, a power supply voltage (Vcc) (e.g., 5.0V) is applied to the second impurity region (R2) and the first impurity region (R1) may be floated.

When data stored in the fourth charge trap layer (CTL4) is selectively erased (ERS4), a fourth erase voltage (e.g., −7.5V) may be applied to the gate electrode (G). Simultaneously, a power supply voltage (Vcc) (e.g., 5.0V) is applied to the second impurity region (R2) and the first impurity region (R1) may be floated. Data trapped in the second charge trap layer (CTL2) may be also simultaneously erased.

Referring to FIG. 5B, a read operation is performed to confirm whether a semiconductor device is in a program condition or an erase condition. A read direction may be opposite to a program direction. A read voltage (V_{read}) (e.g., 3.3V) may be applied to the gate electrode (G) in order to read data (READ 1, 3) stored in the first and third charge trap layers (CTL1 and CTL3). A ground voltage may be applied to the first impurity region (R1) and a voltage of about 1V may be applied to the second impurity region (R2). Charges move, so that a read operation may be performed toward a third direction \textcircled{3}. For example, a threshold voltage Vₜₕ when data is stored in the first and third charge trap layers (CTL1 and CTL3) may be grater than a threshold voltage Vₜₕ when data is stored only in the first charge trap layer (CTL1).

A read voltage (V_{read}) (e.g., 3.3V) may be applied to the gate electrode (G) in order to read data (READ 2, 4) stored in the second and fourth charge trap layers (CTL2 and CTL4). A ground voltage may be applied to the second impurity region (R2) and a voltage of about 1V may be applied to the first impurity region (R2). Charges move, so that a read operation may be performed toward a fourth direction \textcircled{4}. For example, a threshold voltage Vth when data is stored in the second and fourth charge trap layers (CTL2 and CTL4) may be greater than a threshold voltage Vₜₕ when data is stored only in the second charge trap layer (CTL2).

The program voltage, the erase voltage, the read voltage and the power supply voltage may be controlled by such factors as a design rule of a semiconductor device, a charge storage capacitance of a semiconductor device and a thickness of an insulating layer used in a semiconductor device for example.

Referring to FIGS. 1 through 2B and 6 through 11, a method of forming a semiconductor device according to some embodiments.

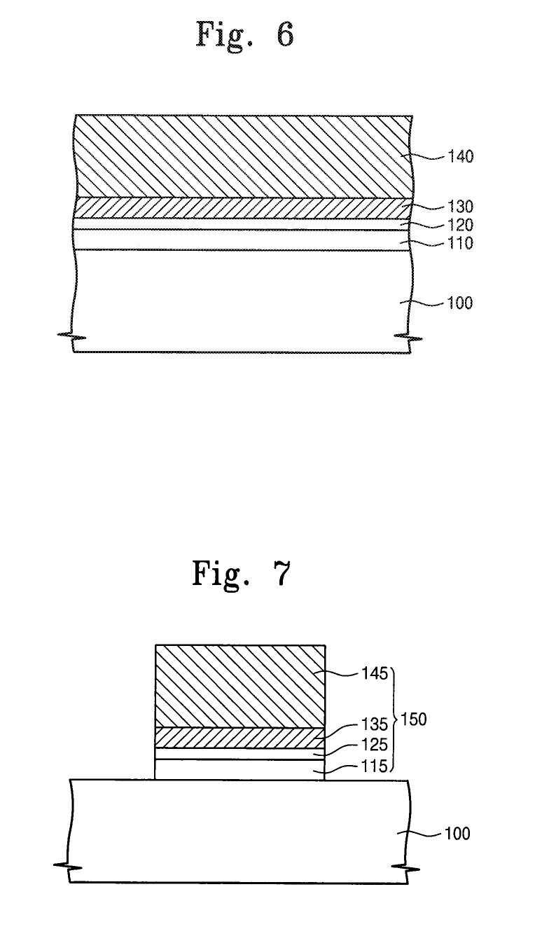

Referring to FIG. 6, a substrate 100 may be provided. The substrate 100 is a semiconductor substrate (e.g., a silicon wafer). The substrate 100 may also be silicon on insulator (SOI). A first barrier layer 110, a middle insulating layer 120, a second barrier layer 130 and a conductive layer 140 may be sequentially formed on the substrate 100. The first barrier layer 110 may include material having a high etching selectivity with respect to the substrate 100, the middle insulating layer 120, the second barrier layer 130 and the conductive layer 140. The second barrier layer 130 may include material having a high etching selectivity with respect to the substrate 100, the middle insulating layer 120, the first barrier layer 110 and the conductive layer 140.

The first barrier layer 110 may include an insulating material (e.g., a silicon oxide layer (SiO₂)). The silicon oxide layer may be formed using an oxidation process such as a thermal oxidation and a radical oxidation, or a chemical vapor deposition process. The middle insulating layer 120 may include an insulating material (e.g., a high dielectric constant material) different from the first barrier layer 110. The middle insulating layer 120 may include a metal oxide (e.g., an aluminum oxide layer, a hafnium aluminum oxide layer, a lanthanum oxide layer, a lanthanum aluminum oxide layer or a lanthanum hafnium oxide layer). The second barrier layer 130 may include a conductive material. For example, the second barrier layer 130 may include a doped polysilicon germanium. The conductive layer 140 may include a conductive material (e.g., doped polysilicon) different from the second barrier layer 130.

Referring to FIG. 7, a patterning process applied to the conductive layer 140, the second barrier layer 130, the middle insulating layer 120 and the first barrier layer 110 may be performed. A stacked structure 150 including a first barrier pattern 115, a middle insulating pattern 125, a second barrier pattern 135 and a conductive pattern 145 may be formed by the patterning process. The stacked structure 150 may include sidewalls parallel to each other, and side surfaces of each of the first barrier pattern 115, the middle insulating pattern 125, the second barrier pattern 135 and the conductive pattern 145 may be aligned to the sidewalls of the stacked structure 150.

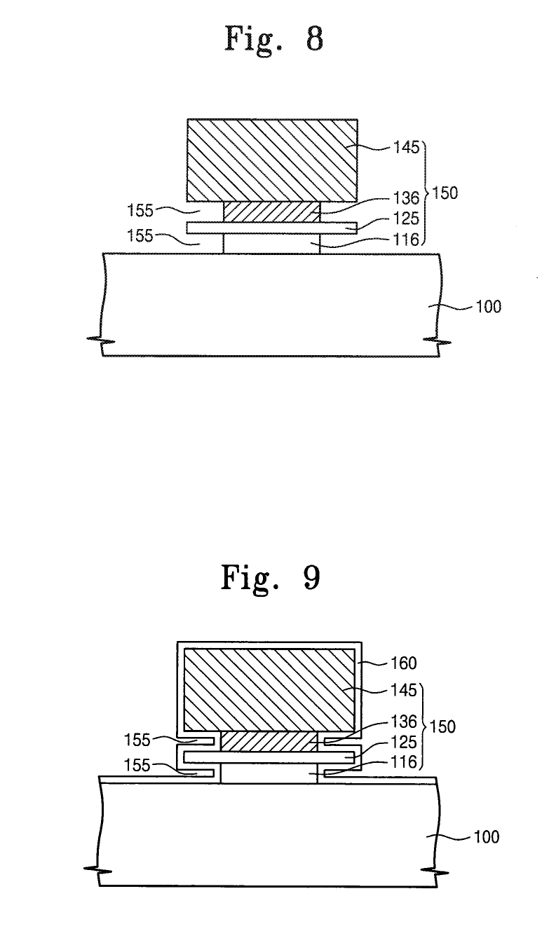

Referring to FIG. 8, a portion of the side surface of the first barrier pattern 115 is removed to form a first barrier 116. The first barrier 116 may be formed by an etching process having a high etch selectivity for the first barrier pattern 115. The etching process may be an isotropic etching process using a compound including fluorine. For instance, the etching process may be a wet etching process using a solution including hydrofluoric acid (HF) and/or fluoride ammonium (NH₄F). The etched amount of the first barrier pattern 115 from the both side surfaces may be equal.

A portion of the side surface of the second barrier pattern 135 is removed to form a second barrier 136. The second barrier 136 is formed by an etching process having high etch selectivity for the second barrier pattern 135. The second barrier pattern 135 may be etched by a solution including hydrofluoric acid (HF) and/or nitric acid (HNO₃). The etched amount of the second barrier pattern 135 from the both side surfaces may be equal. Spaces 155 may be formed on the sidewalls of the stacked structure 150.

The first barrier 116 may be formed after the second barrier 136 is formed.

Referring to FIG. 9, a first insulating layer 160 may be formed on a surface of the stacked structure 150 including the spaces 155. The first insulating layer 160 may extend onto the substrate 100. The first insulating layer 160 may include an oxide. A surface of the stacked structure 150 may include a first surface which is inside of the spaces 155 and a second surface which is outside of the spaces 155 except the first surface. The first insulating layer 160 may be formed on the first and second surfaces using a deposition process such as a chemical vapor deposition process or an atomic layer deposition process.

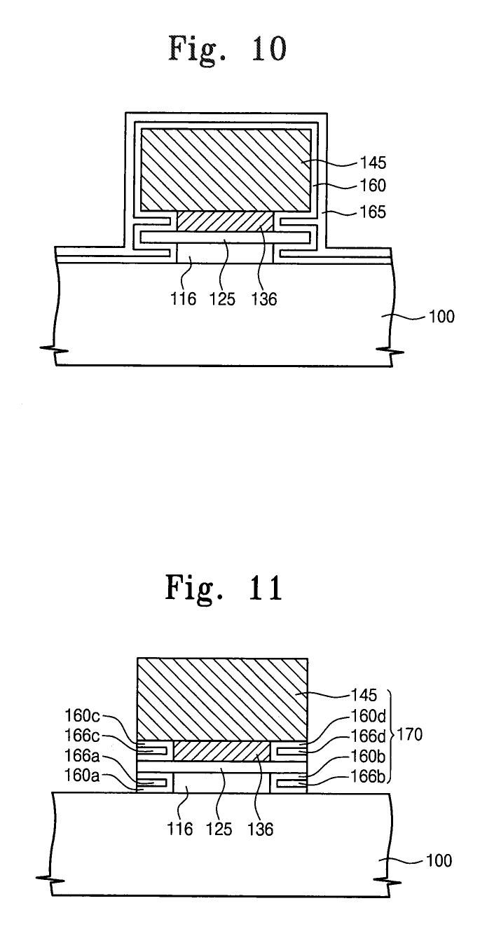

Referring to FIG. 10, a second insulating layer 165 may be formed on the first insulating layer 160. The second insulating layer 165 may be formed so as to fill up the spaces 155 and may extend onto the substrate 100. The second insulating layer 165 has a charge trap site and for instance, may include silicon nitride and/or nano crystal. The second insulating layer 165 may be formed using a chemical vapor deposition process and an atomic layer deposition process.

Referring to FIG. 11, the second insulating layer 165 formed on the substrate 100 and the second surface is removed to form charge trap layers 166a, 166b, 166c and 166d in the spacers 155. As a result, a gate structure 170 may be formed. The second insulating layer 165 may be removed using an isotropic etching process. At this time, a portion of the second insulating layer 165 may be remained in the surfaces 155 by controlling an etching time of the isotropic etching process. The first insulating layer 160 on the second surface may be removed by the isotropic etching process. The first insulating layer 160 may be selectively removed by a separate process. Thus, insulating patterns 160a, 160b, 160c and 160d surrounding surfaces of the charge trap layers 166a, 166b, 166c and 166d except one side surfaces (outer side surfaces) aligned to sidewalls of the gate structure 170 may be formed.

Referring to FIGS. 11 and 1, impurity regions 180 and 185 may be formed in the substrate 100 adjacent to side surfaces of the gate structure 170 by performing an ion implantation process.

Referring to FIGS. 2A and 2B again, a spacer 162 may be further formed on a side surface of the gate structure 170 of FIG. 11.

Referring to FIG. 2A, the spacer 162 may be formed using an oxidation process. A surface of the substrate 100, an exposed surface of the conductive pattern 145 and exposed side surfaces of the charge trap layers 166a, 166b, 166c and 166d may be oxidized by the oxidation process. After that, an anisotropic etching process may be performed. Thus, the surfaces of the charge trap layers 166a, 166b, 166c and 166d may be protected by the spacer 162. The impurity regions 180 and 185 may be formed before the spacer 162 is formed or after the spacer 162 is formed.

Referring to FIG. 2B, the spacer 162 may be formed using a chemical vapor deposition process. After the spacer insulating layer is formed using the chemical vapor deposition process, an anisotropic etching process may be performed. Thus, a surface of the charge trap layer 166 may be protected by the spacer 162. The impurity regions 180 and 185 may be formed before the spacer 162 is formed or after the spacer 162 is formed.

Referring to FIGS. 3 through 4B and 12 through 17, a method of forming a semiconductor device according to other embodiments. A description of common features already discussed above will be omitted or briefly described.

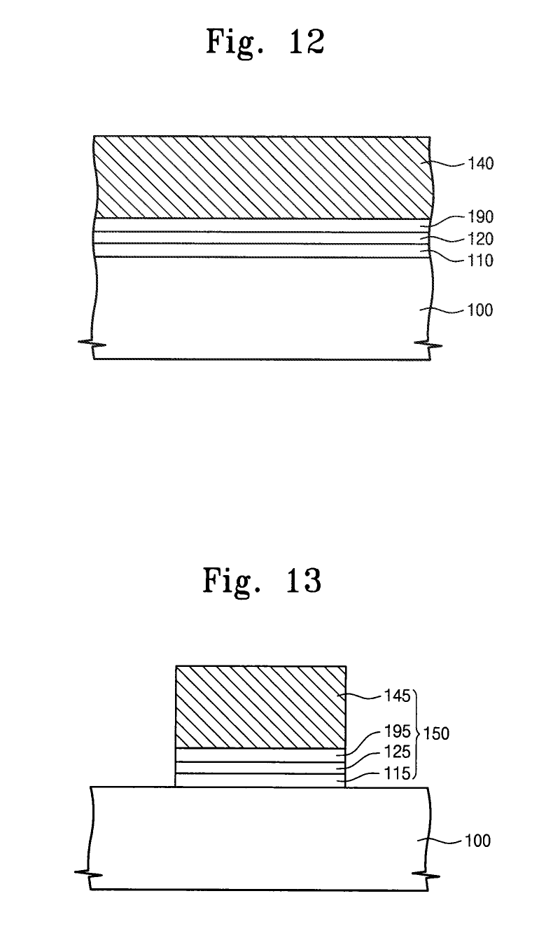

Referring to FIG. 12, a first barrier layer 110, a middle insulating layer 120, a second barrier layer 190 and a conductive layer 140 may be sequentially formed on a substrate 100. The first and second barrier layers 110 and 190 may include a material having an etching selectivity higher than the substrate 100, the middle insulating layer 120 and the conductive layer 140. The first and second barrier layers 110 and 190 may include an insulating material (e.g., a silicon oxide layer). The middle insulating layer 120 may include an insulating material different from the first barrier layer 110 (e.g., a high dielectric constant material). The middle insulating layer 120 may include metal oxide such as an aluminum oxide layer, a hafnium aluminum oxide layer, a lanthanum oxide layer, a lanthanum aluminum oxide layer or a lanthanum hafnium oxide layer. The conductive layer 140 may include a conductive polysilicon.

Referring to FIG. 13, a patterning process applied to the conductive layer 140, the second barrier layer 190, the middle insulating layer 120 and the first barrier layer 110 may be performed. A stacked structure 150 including a first barrier pattern 115, a middle insulating pattern 125, a second barrier pattern 195 and a conductive pattern 145 may be formed by the patterning process. The stacked structure 150 may include sidewalls parallel to each other, and one side surface of each of the first barrier pattern 115, the middle insulating pattern 125, the second barrier pattern 195 and the conductive pattern 145 may be aligned to the sidewalls of the stacked structure 150.

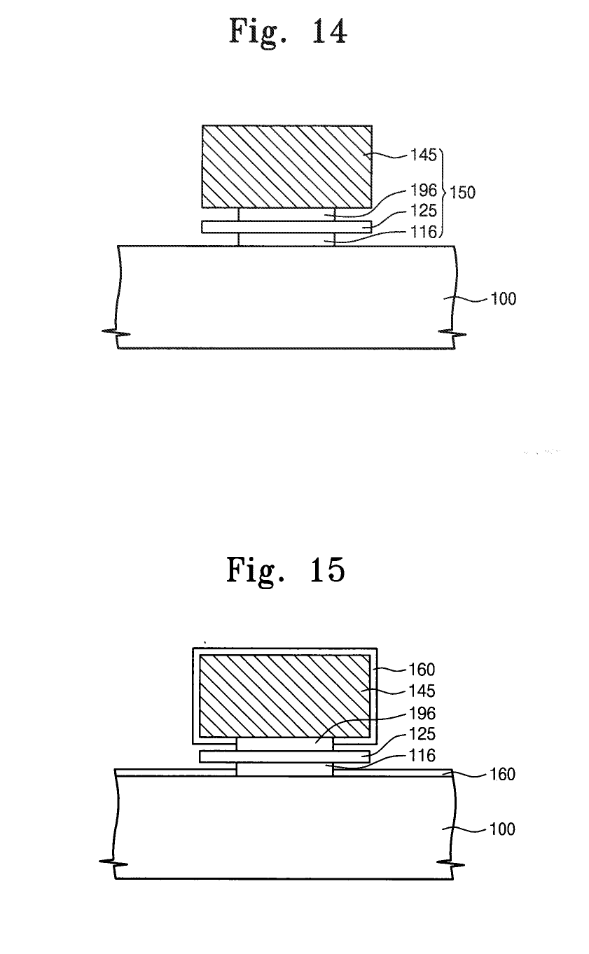

Referring to FIG. 14, portions of side surfaces of the first and second barrier patterns 115 and 195 are removed to form a first barrier 116 and a second barrier 196. The first and second barriers 116 and 196 may be simultaneously formed by an etching process having a high etch selectivity to the first and second barrier patterns 115 and 196. The etching process may be an etching process using a compound (e.g., fluorocarbon compound) including fluorine. The etching process may be an etching process using a solution including hydrofluoric acid (HF) and/or fluoride ammonium (NH₄F). Spaces 155 may be formed on the sidewalls of the stacked structure 150 by the above etching processes. The stacked structure 150 may include a first surface which is inside of the spaces 155 and a second surface which is outside of the spaces 155 except the first surface.

Referring to FIG. 15, a first insulating layer 160 may be formed. The first insulating layer 160 may include an oxide. When the first insulating layer 160 is formed using an oxidation process such as a thermal oxidation process, the first insulating layer 160 may be selectively formed on an exposed surface of the conductive pattern 145 and on the substrate 100.

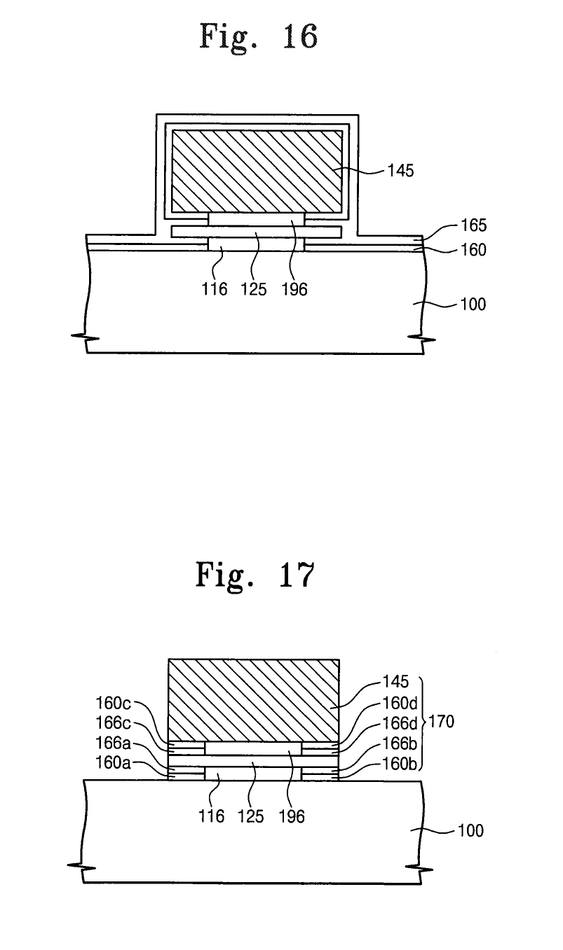

Referring to FIG. 16, a second insulating layer 165 may be formed on the stacked structure 150 and the substrate 100 so as to fill up the spaces 155. The second insulating layer 165 has a charge trap site and may include silicon nitride and/or nano crystal. The second insulating layer 165 may be formed using a chemical vapor deposition process or an atomic layer deposition process.

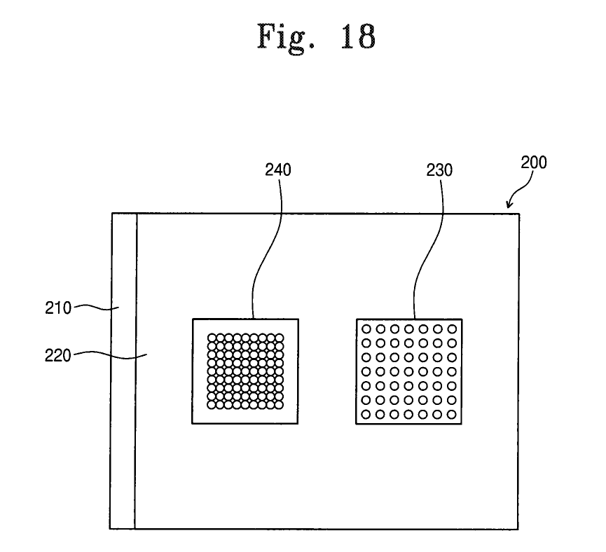

Referring to FIG. 17 and 3, the second insulating layer 165 on the substrate 100 and the second surface is removed to form charge trap layers 166a, 166b, 166c and 166d in the spaces 155. Thus, a gate structure 170 may be formed. When the second insulating layer 165 is removed, the first insulating layer 160 on the second surface may also be removed. Impurity regions 180 and 185 may be formed in the substrate 100 adjacent to side surfaces of the gate structure 170 by performing an ion implantation process.

Referring to FIGS. 4A and 4B again, a spacer 162 may be further formed on side surface of the gate structure 170 of FIG. 17.

Referring to FIG. 4A, the spacer 162 may be formed using an oxidation process. A surface of the substrate 100, an exposed surface of the conductive pattern 145 and exposed side surfaces of the charge trap layers 166a, 166b, 166c and 166d may be oxidized by the oxidation process. After that, an anisotropic etching process may be performed. Thus, the surfaces of the charge trap layers 166a, 166b, 166c and 166d may be protected by the spacer 162. The impurity regions 180 and 185 may be formed before the spacer 162 is formed or after the spacer 162 is formed.

Referring to FIG. 4B, the spacer 162 may be formed using a chemical vapor deposition process. After the spacer insulating layer is formed using the chemical vapor deposition process, an anisotropic etching process may be performed. Thus, surfaces of the charge trap layers 166a, 166b, 166c, 166d may be protected by the spacer 162. The impurity regions 180 and 185 may be formed before the spacer 162 is formed or after the spacer 162 is formed.

Referring to FIG. 18, a modular memory device 200 including a semiconductor device according to an embodiment is described.

A modular memory device 200 may include a printed circuit board 220. The printed circuit board 220 may form one of external surfaces of the modular memory device 200. The printed circuit board 220 may support a memory unit 230, a device interface unit 240 and electrical connector 210.

The memory unit 230 may include a three-dimensional memory array that includes cells of semiconductor devices as described with reference to FIGS. 1-4B, and may be connected to a memory array controller. The memory array controller may include appropriate memory cells arranged in a three dimensional lattice on a board.

The device interface unit 240 is formed on a divided board and may be electrically connected to the memory unit 230 and the electrical connector 210 by the printed circuit board. The memory unit 230 and the device interface unit 240 may be directly mounted on the printed circuit board 220. The device interface unit 240 may include components to generate a voltage, a clock frequency and protocol logic.

Embodiments of inventive concepts exemplarily described herein may be practiced in many ways. What follows below is a non-limiting discussion of some embodiments inventive concepts exemplarily described herein.

One embodiment exemplarily described herein may be characterized as a method of forming a semiconductor device that includes: forming a stacked structure including a first barrier layer, a middle insulating layer, a second barrier layer and a conductive layer that are sequentially stacked on a substrate; forming spaces at the stacked structure by removing a portion of the first and second barrier layers exposed on both sidewalls of the stacked structure; forming charge trap layers in the spaces; and forming an impurity region in the substrate, adjacent to the stacked structure.

In one embodiment, the method of forming a semiconductor device of claim may further include forming a spacer on exposed surfaces of the charge trap layers.

In one embodiment, in the method of forming a semiconductor device, the second barrier layer may include a conductive material, and the first barrier layer may include an insulating material. The method of forming the spaces may include selectively etching the first barrier layer; and selectively etching the second barrier layer.

In one embodiment, in the method of forming a semiconductor device, the first and second barrier layers may comprise same insulating material. The method of forming the spaces may include selectively etching the first and second barrier layers at the same time.

In one embodiment, after forming the spaces, the method of forming a semiconductor device may further include forming an insulating layer on a surface of the stacked structure.

In one embodiment, the method of forming the insulating layer may include oxidizing the conductive layer and a surface of the substrate.

In one embodiment, the stacked structure may include a first surface which is inside of the spaces and a second surface which is outside of the spaces. The forming of the charge trap layers may include: uniformly forming an insulating layer on the first and second surfaces so as to fill up the spaces; and removing the insulating layer on the second surface.

In one embodiment, the insulating layer may formed by performing a chemical vapor deposition process or an atomic layer deposition process.

Another embodiment exemplarily described herein may be characterized as a method of operating a semiconductor device including a gate electrode on a substrate, a first charge trap layer interposed between the substrate and the gate electrode, a second charge trap layer which is interposed between the substrate and the gate electrode and spaced apart from the first charge trap layer, a third charge trap layer interposed between the first charge trap layer and the gate electrode, a fourth charge trap layer interposed between the second charge trap layer and the gate electrode, a first impurity region in the substrate adjacent to the first charge trap layer and a second impurity region in the substrate adjacent to the second charge trap layer. The method may include: applying a higher voltage to the first impurity region than the second impurity region; and injecting electrons into the first trap layer or the third trap layer by applying a program voltage to the gate electrode.

In one embodiment, in the method of operating a semiconductor device, a program voltage which programs one of the third charge trap layer and the fourth charge trap layer may be higher than a program voltage which programs one of the first charge trap layer and the second charge trap layer.

In one embodiment, the method of operating a semiconductor device may further include applying an erase voltage having a direction opposite to a direction of the program voltage, to the gate electrode.

In one embodiment, the erase voltage may be applied by erasing data from each of the charge trap layers or all of the charge trap layers.

In one embodiment, the method of operating a semiconductor device may further include applying a higher voltage to the second impurity region than the first impurity region; and reading a program condition of the first charge trap layer or the third charge trap layer by applying a read voltage to the gate electrode.

1. A semiconductor device comprising:
a gate electrode on a substrate;
a first charge trap layer interposed between the substrate and the gate electrode;
a second charge trap layer which is interposed between the substrate and the gate electrode and is spaced apart from the first charge trap layer;
a third charge trap layer interposed between the first charge trap layer and the gate electrode;
a fourth charge trap layer which is interposed between the second charge trap layer and the gate electrode and is spaced apart from the third charge trap layer; and
an impurity region in the substrate.

2. The semiconductor device of claim 1, further comprising a first barrier layer interposed between the first charge trap layer and the second charge trap layer, and a second barrier layer interposed between the third charge trap layer and the fourth charge trap layer,
wherein the first and second barrier layers include a material having an etching selectivity higher than the gate electrode.

3. The semiconductor device of claim 1, further comprising a first insulating pattern interposed between the substrate and the first charge trap layer and a second insulating pattern interposed between the substrate and the second charge trap layer.

4. The semiconductor device of claim 1, further comprising a third insulating pattern interposed between the third charge trap layer and the gate electrode and a fourth insulating pattern interposed between the fourth charge trap layer and the gate electrode.

5. The semiconductor device of claim 1, further comprising a middle insulating layer interposed between the first charge trap layer and the third charge trap layer; and
the middle insulating layer interposed between the second charge trap layer and the fourth charge trap layer.

6. The semiconductor device of claim 1, wherein the gate electrode includes a first sidewall and a second sidewall which are parallel to each other and wherein the first charge trap layer and the third charge trap layer are aligned with the first sidewall and the second charge trap layer and the fourth charge trap layer are aligned with the second sidewall.

7. The semiconductor device of claim 1, further comprising a spacer disposed on exposed sidewalls of the first, the second, the third, and the fourth charge trap layers.

8. An array of memory cells formed on a semiconductor substrate, at least one memory cell in the array of memory cells comprising:
a first charge trap layer and a second charge trap layer separated from one another by a first barrier, the first and second charge trap layers separated from the substrate by first and second insulating patterns, respectively;
a third charge trap layer and a fourth charge trap layer separated from one another by a second barrier;
third and fourth insulating patterns adjacent to the third and fourth charge trap layers, respectively; and
a conductive pattern disposed on the third and fourth insulating patterns.

9. The memory cell array of claim 8 in which the first barrier and second barrier are formed from the same material.

10. The memory cell array of claim 8 in which the second barrier is made from an electrically conductive material.

11. The memory cell array of claim 8 in which the first charge trap layer and the second charge trap layer have substantially similar storage capacitances.

12. The memory cell array of claim 8, further comprising a middle insulating pattern that separates the first and second insulating patterns from the third and fourth insulating patterns.

13. The memory cell array of claim 8 in which the conductive pattern includes a first sidewall to which edges of the first and third charge trap layers are aligned, and in which the conductive pattern includes a second sidewall, parallel to the first sidewall, to which edges of the second and fourth charge trap layers are aligned.

14. A memory device, comprising:
a printed circuit board;
a memory unit including an array of memory cells formed on a semiconductor substrate and in which at least one of the cells includes:
an impurity region in the substrate,
a gate electrode,
first and second charge trap layers interposed between the substrate and the gate electrode, the first charge trap layer and the second charge trap layer separated from one another, and
third and fourth charge trap layers formed between the substrate and the gate electrode, the third charge trap layer and the fourth charge trap layer separated from one another.

15. The memory device of claim 14 in which the at least one of the cells further comprises:
first and second insulating patterns interposed between the substrate and the first and second charge trap layers, respectively.

16. The memory device of claim 15 in which the at least one of the cells further comprises:
third and fourth insulating patterns interposed between the gate electrode and the third and fourth charge trap layers, respectively.

17. The memory device of claim 14 in which the at least one of the cells further comprises:
a middle insulating pattern disposed between the first charge trap layer and the third charge trap layer.

18. The memory device of claim 14 in which the at least one of the cells further comprises:
a first barrier separating the first and second charge trap layers; and
a second barrier separating the third and fourth charge trap layers.

19. The memory device of claim 14 in which the gate electrode includes a first sidewall to which edges of the first and third charge trap layers are aligned, and in which the gate electrode includes a second sidewall, parallel to the first sidewall, to which edges of the second and fourth charge trap layers are aligned.

20. The memory device of claim 14, further comprising:
a memory device interface unit mounted to the printed circuit board and coupled to the memory unit.

21-33. (canceled)
